(19) United States
(12) Patent Application Publication
(10) Pub. No.: US 2026/0223732 A1
(43) Pub. Date: Jul. 30, 2026

(54) ELECTRONIC DEVICE

(71) Applicant: Advanced Semiconductor Engineering, Inc., Kaohsiung (TW)

(72) Inventors: Ying-Chung CHEN, Taoyuan (TW); Hsin-Ying HO, Taoyuan (TW)

(73) Assignee: Advanced Semiconductor Engineering, Inc., Kaohsiung (TW)

(21) Appl. No.: 19/037,021

(22) Filed: Jan. 24, 2025

(51) Int. Cl. H01L 25/16; G02B 6/42; H01L 23/498; H01L 23/538; H04B 10/40; H10F 55/00

(52) U.S. Cl. CPC H10W 90/00; H10F 55/00; H10W 70/611; H10W 90/401; G02B 6/4246; H04B 10/40; H10W 90/701

(57) ABSTRACT

The present disclosure provides an electronic device. The electronic device includes a carrier, an interposer disposed over the carrier, an optical transceiver disposed over the interposer, and an electronic component supporting optical transceiver and supported by the interposer.

### BACKGROUND

### 1. Technical Field

The present disclosure relates to an electronic device.

### 2. Description of the Related Art

Optical component arrays (such as LEDs and photodiodes (PDs)) can be mounted on a carrier and electrically connected, with an optical channel established between them via optical fibers. To avoid bandwidth limitations imposed by the carrier's pitch, 2.3D or 2.5D technology can be utilized to support more optical components. However, these technologies come with higher manufacturing costs, and the dielectric materials may cause optical signal crosstalk due to their light-transmitting properties.

### SUMMARY

In some arrangements, an electronic device includes a carrier, an interposer disposed over the carrier, an optical transceiver disposed over the interposer, and an electronic component supporting optical transceiver and supported by the interposer.

In some arrangements, an electronic device includes a lower-density circuit, a first higher-density circuit disposed over the lower-density circuit, and an optical transceiver disposed over the first higher-density circuit and including a transmitting region and a receiving region. The first higher-density circuit is configured to reduce optical crosstalk between the transmitting region and the receiving region.

In some arrangements, an electronic device includes a circuit structure, and an optical transceiver disposed over the circuit structure and including a transmitting region and a receiving region. The electronic device also includes a first light blocking structure supporting the optical transceiver and configured to reduce an optical crosstalk between the transmitting region and the receiving region.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1A illustrates a cross-sectional view of an electronic device in accordance with some arrangements of the present disclosure.

FIG. 1B illustrates a cross-sectional view of an electronic device in accordance with some arrangements of the present disclosure.

FIG. 1C illustrates a cross-sectional view of a part of the electronic device of FIG. 1A in accordance with some arrangements of the present disclosure.

FIG. 1D illustrates a cross-sectional view of a part of an electronic device in accordance with some arrangements of the present disclosure.

FIG. 1E illustrates a cross-sectional view of a part of an electronic device in accordance with some arrangements of the present disclosure.

FIG. 1F illustrates a cross-sectional view of a part of an electronic device in accordance with some arrangements of the present disclosure.

FIG. 1G illustrates a cross-sectional view of a part of an electronic device in accordance with some arrangements of the present disclosure.

FIG. 1H illustrates a cross-sectional view of a part of an electronic device in accordance with some arrangements of the present disclosure.

FIG. 1I illustrates a cross-sectional view of an electronic device in accordance with some arrangements of the present disclosure.

FIG. 1J illustrates a perspective view of an electronic device in accordance with some arrangements of the present disclosure.

FIG. 2A illustrates a cross-sectional view of an electronic device in accordance with some arrangements of the present disclosure.

FIG. 2B illustrates a cross-sectional view of an electronic device in accordance with some arrangements of the present disclosure.

FIG. 3A illustrates a cross-sectional view of an electronic device in accordance with some arrangements of the present disclosure.

FIG. 3B illustrates a cross-sectional view of an electronic device in accordance with some arrangements of the present disclosure.

FIG. 3C illustrates a cross-sectional view of an electronic device in accordance with some arrangements of the present disclosure.

FIG. 4A, FIG. 4B, FIG. 4C, and FIG. 4D illustrate cross-sectional views in one or more stages of a method of manufacturing a part of an electronic device in accordance with an embodiment of the present disclosure.

FIG. 5A, FIG. 5B, FIG. 5C, and FIG. 5D illustrate cross-sectional views in one or more stages of a method of manufacturing an electronic device in accordance with an embodiment of the present disclosure.

FIG. 5C′ illustrate a cross-sectional view in one or more stages of a method of manufacturing an electronic device in accordance with an embodiment of the present disclosure.

FIG. 6A, FIG. 6B, FIG. 6C, and FIG. 6D illustrate cross-sectional views in one or more stages of a method of manufacturing an electronic device in accordance with an embodiment of the present disclosure.

FIG. 6C′ illustrate a cross-sectional view in one or more stages of a method of manufacturing an electronic device in accordance with an embodiment of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

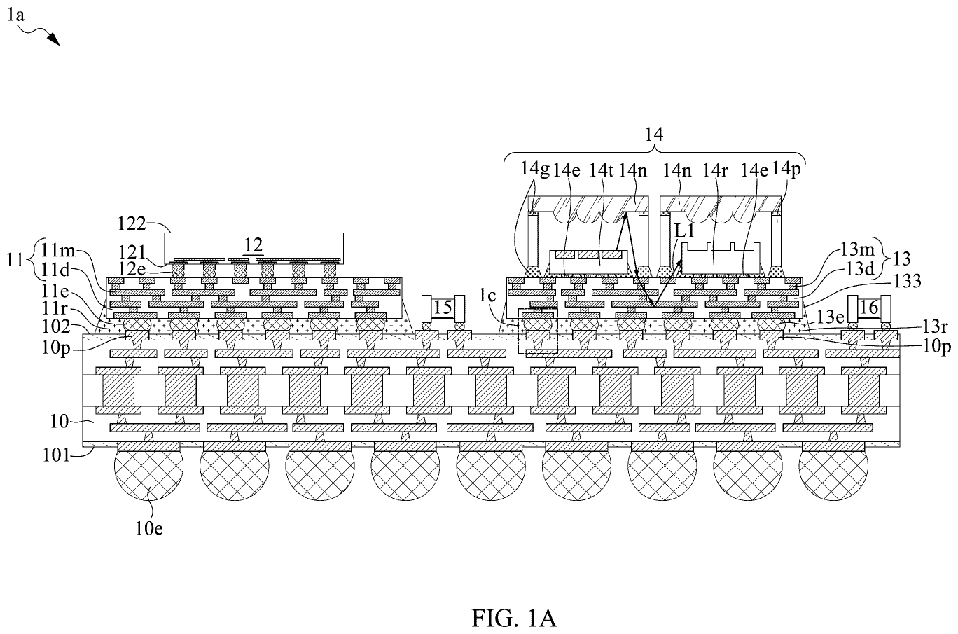

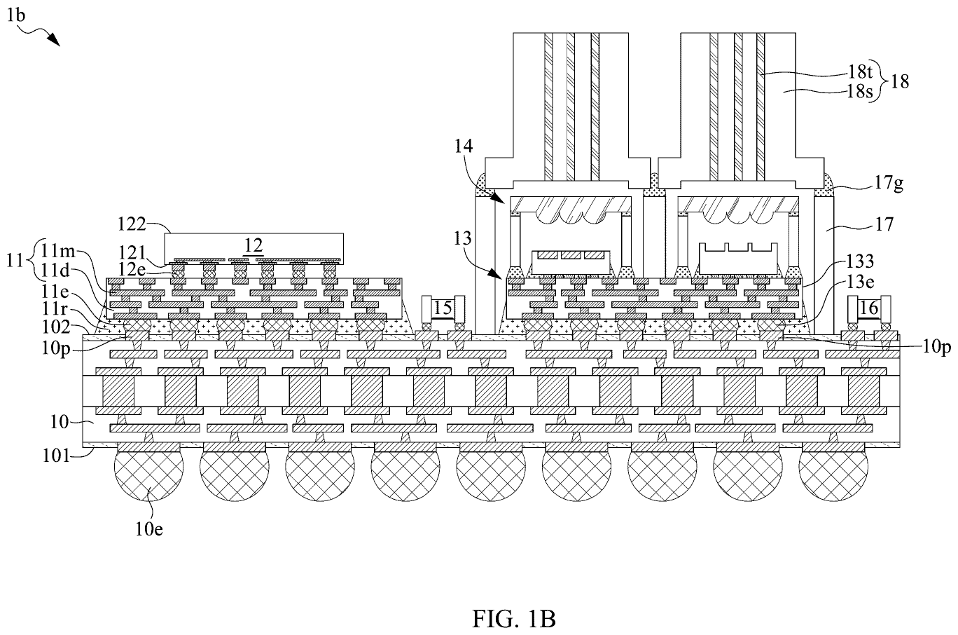

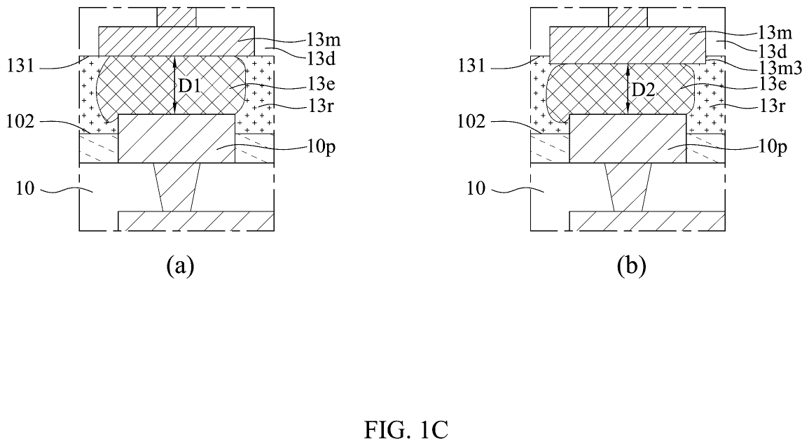

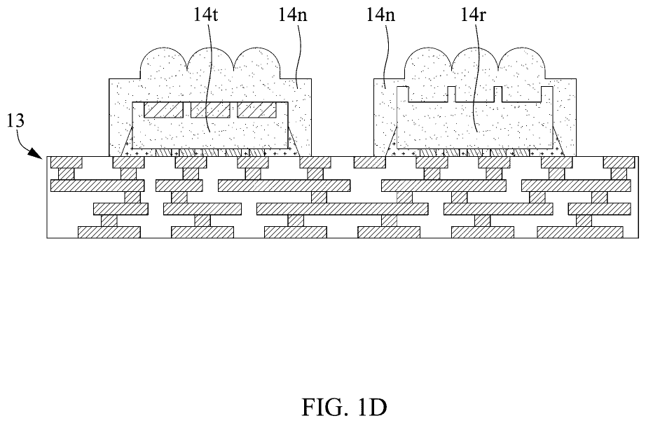

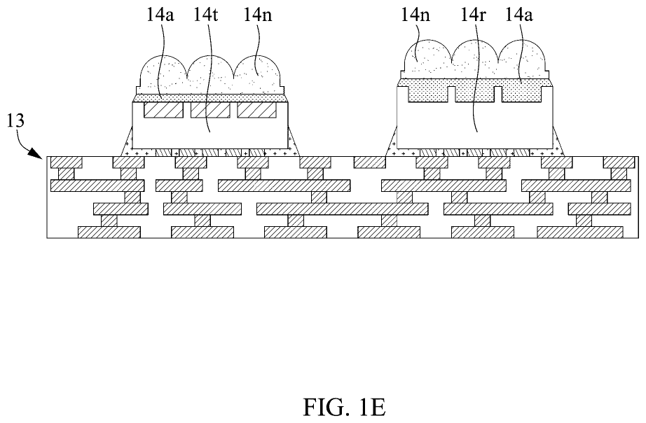

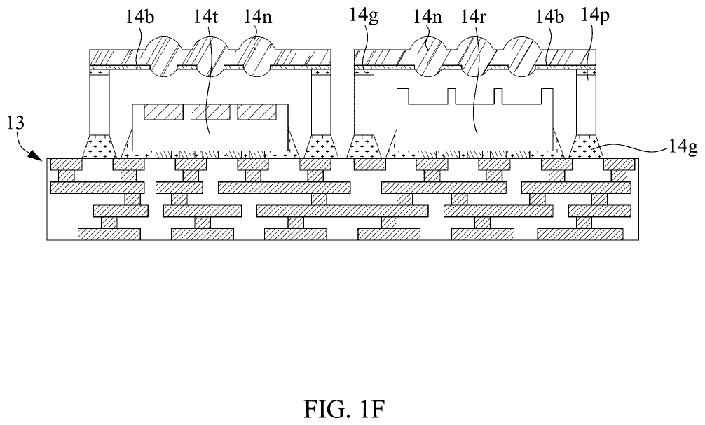

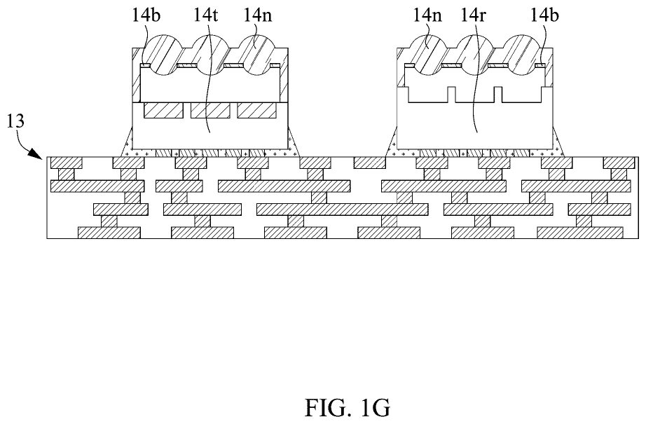

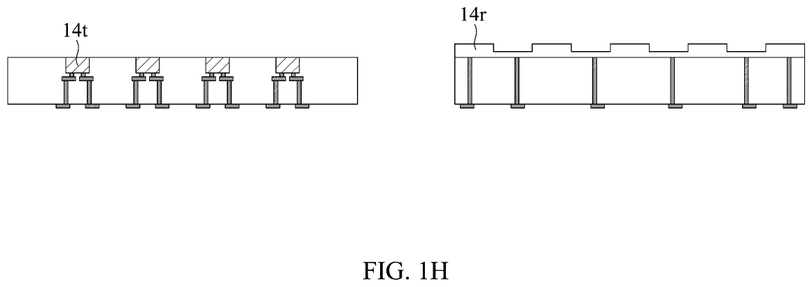

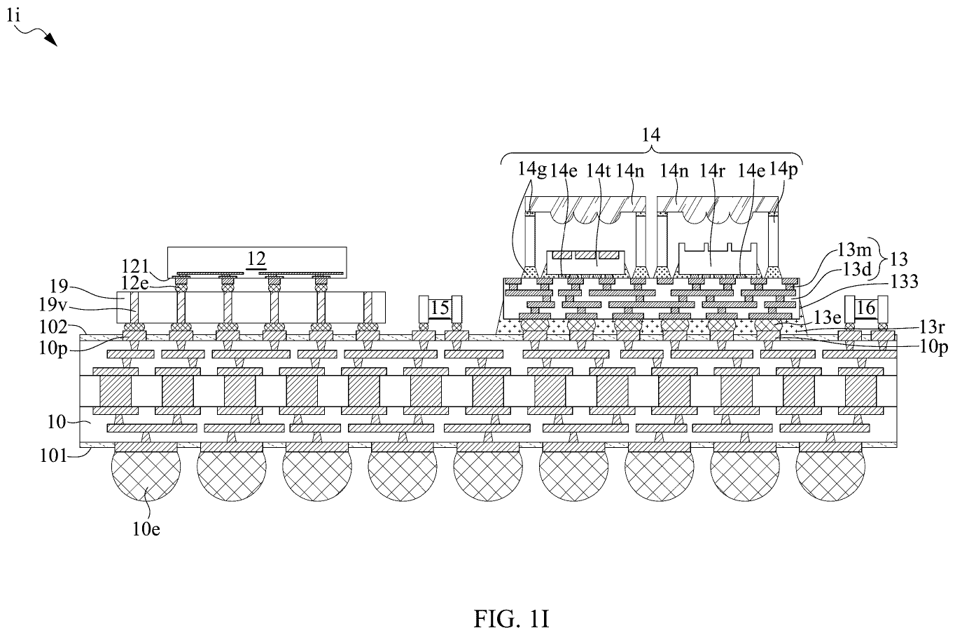

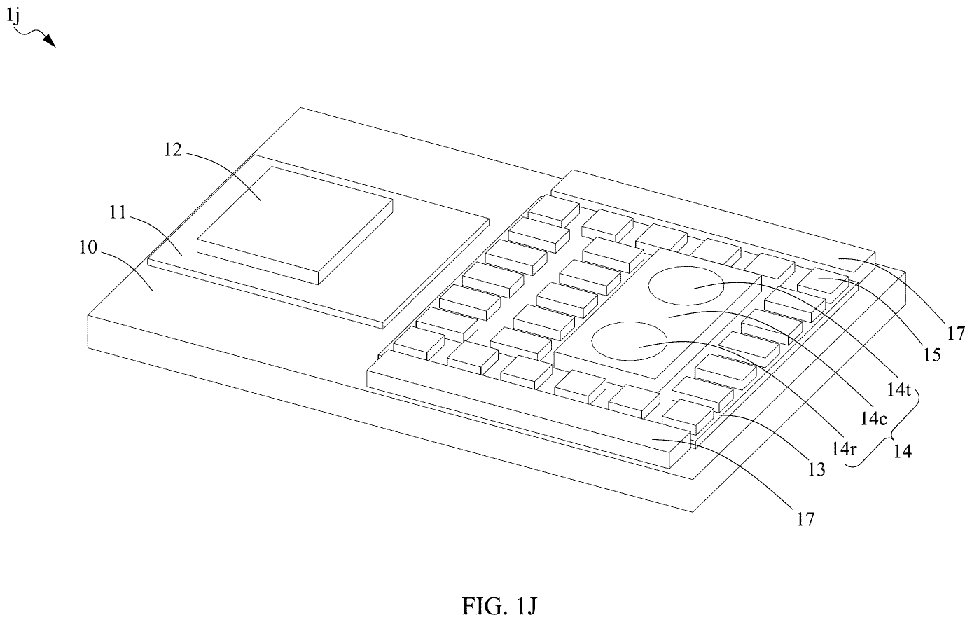

FIG. 1A illustrates a cross-sectional view of an electronic device 1a in accordance with some arrangements of the present disclosure.

In some arrangements, the electronic device 1a may include a package, such as a semiconductor device package. In some arrangements, the electronic device 1a may include carriers 10, 11, 13, electronic components 12, 15, 16, and an optical component 14.

The carrier 10 may include a substrate. In some arrangements, the carrier 10 may include, for example, a printed circuit board (PCB), such as a paper-based copper foil laminate, a composite copper foil laminate, or a polymer-impregnated glass-fiber-based copper foil laminate.

In some arrangements, the carrier 10 may include an interconnection structure or a circuit structure. The circuit structure may include a redistribution layer (RDL), a circuit layer, a conductive pillar, conductive pad, conductive trace, a conductive via, a conductive wire, or other conductive elements. The circuit structure may provide electrical connections for the components connected with the carrier 10.

The carrier 10 may include a surface 101 and a surface 102 opposite to the surface 101. The carrier 10 may include one or more conductive pads in proximity to, adjacent to, or embedded in and exposed by the surface 101 and/or the surface 102. The carrier 10 may include a solder resist on the surface 101 and/or the surface 102 to fully expose or expose at least a portion of the conductive pads for electrical connections.

For example, the carrier 10 may include conductive pads 10p adjacent to the surface 102 of the carrier 10. In some arrangements, the conductive pads 10p may protrude from the surface 102 of the carrier 10. For example, the conductive pads 10p may protrude or extend beyond the surface 102 of the carrier 10.

The conductive pad 10p may be disposed under or below the carrier 11 and electrically connected with the carrier 11 through an electrical contact 11e. Similarly, the conductive pad 10p may be disposed under or below the carrier 13 and electrically connected with the carrier 13 through an electrical contact 13e.

In some arrangements, the carrier 10 may include an electrical contact 10e adjacent to the surface 101 for providing electrical connections between the electronic device 1a and an external device (e.g., a PCB, another electronic device, an electronic module, and so on).

The carriers 11 and 13 may be disposed over the surface 102 of the carrier 10. The carriers 11 and 13 may be physically separated. For example, the carriers 11 and 13 may not be physically connected. For example, the carriers 11 and 13 may be separated by the electronic component 15.

In some arrangements, the carriers 11 and 13 may each include, for example, an interposer. In some arrangements, the carriers 11 and 13 may each include interposer-like wirings to form a structure which may be regarded as an interposer or a fan-out substrate.

The carrier 11 may be disposed between the carrier 10 and the electronic component 12. For example, the carrier 11 may be configured to structurally support the electronic component 12. The carrier 11 may be configured to provide electrical connections between the carrier 10 and the electronic component 12.

In some arrangements, the carrier 11 may include a high-speed circuitry region and/or a high-density circuitry region. In some arrangements, the carrier 11 may include a high-speed circuit and/or a high-density circuit. For example, the circuit density of the carrier 11 may be relatively higher than that of the carrier 10. The carrier 11 may include a higher-density circuit and the carrier 10 may include a lower-density circuit. For example, the line spacing and/or the pad pitch of the carrier 11 may be relatively narrower than that of the carrier 10.

In some arrangements, a resin 11r may be disposed between the carrier 10 and the carrier 11. The resin 11r may cover, surround or encapsulate the electrical contact 11e. In some arrangements, a connection layer or a conductive paste can be used to connect the carrier 10 and the carrier 11. For example, an epoxy solder paste can be used to form the electrical contact 11e. The epoxy solder paste may include a mixture of solder and epoxy resin. The epoxy solder paste is suitable for low-temperature bonding (around 150 degrees to 170 degrees), which reduces the stress generated by high temperatures. During the curing process, the solder may aggregate between the conductive pads, forming the electrical contact 11e and displacing the resin 11r. For example, the resin 11r may precipitate or separate from the electrical contact 11e. Additionally, the resin 11r may surround the electrical contact 11e, thereby eliminating the need for the underfill process. In some arrangements, the epoxy solder paste may include a Sn-Bi solder or a lead-free alloy with a low melting point.

The resin 11r may cover, surround or encapsulate a part of a lateral surface 113 of the carrier 11. For example, in a direction (such as a horizontal direction) substantially parallel to the surface 101 and/or the surface 102 of the carrier 10, the resin 11r may be overlapped with the carrier 11. In some arrangements, the resin 11r may entirely cover the lateral surface 113 of the carrier 11. In some other arrangements, the lateral surface 113 of the carrier 11 may be exposed (such as entirely exposed or uncovered) from the resin 11r.

In some arrangements, the electrical contact 11e and the resin 11r may be considered a connection layer that includes a conductive element and an encapsulant surrounding the conductive element.

Similarly, the carrier 13 may be disposed between the carrier 10 and the optical component 14. For example, the carrier 13 may be configured to structurally support the optical component 14. The carrier 13 may be configured to provide electrical connections between the carrier 10 and the optical component 14.

In some arrangements, the carrier 13 may include a high-speed circuitry region and/or a high-density circuitry region. In some arrangements, the carrier 13 may include a high-speed circuit and/or a high-density circuit. For example, the circuit density of the carrier 13 may be relatively higher than that of the carrier 10. The carrier 13 may include a higher-density circuit and the carrier 10 may include a lower-density circuit. For example, the line spacing and/or the pad pitch of the carrier 13 may be relatively narrower than that of the carrier 10.

In some arrangements, the circuit density of the carrier 13 may be substantially equal to that of the carrier 11.

Similarly, a resin 13r may be disposed between the carrier 10 and the carrier 13. The resin 13r may cover, surround or encapsulate a part of a lateral surface 133 of the carrier 13. The detailed properties and characteristics of the resin 13r are similar to those of resin 11r and will not be repeated here for conciseness.

In some arrangements, the carrier 13 may be configured to function as a light blocking structure. For example, the optical component 14 may include a transceiver having a transmitter 14t and a receiver 14r. The carrier 13 may be non-transmissive to the light emitted from the transmitter 14t. For example, the carrier 13 may be configured to block, reflect, scatter, or absorb the light L1 emitted from the transmitter 14t. For example, the carrier 13 may be configured to prevent undesired light from being inadvertently detected by the receiver 14r. For example, the carrier 13 may be configured to reduce light crosstalk (optical signal crosstalk or optical crosstalk) between the transmitter 14t and the receiver 14r.

In some arrangements, the carrier 11 may include metal 11m and dielectric 11d. Similarly, the carrier 13 may include metal 13m and dielectric 13d.

The metal 11m and the metal 13m may each include a connector, such as a conductive terminal, a conductive layer, conductive pillar, conductive pad, conductive trace, a conductive via, a conductive wire, or another feasible connector. The dielectric 11d and the dielectric 13d may each include an epoxy resin having fillers, a molding compound (e.g., an epoxy molding compound or another molding compound), ajinomoto build-up film (ABF), etc. The dielectric 11d and the dielectric 13d may each include an opaque material, such as ink, carbon black, photoresist, or other non-transparent materials or low transparent materials.

In some arrangements, the carriers 11 and 13 may each include multiple layers. For example, the carriers 11 and 13 may each include 2 to 4 metal layers (or conductive layers). For example, the carriers 11 and 13 may each include 2 to 4 dielectric layers (or light blocking layers). The number of layers in the carriers 11 and 13 may be chosen based on the input/output (I/O) pins.

The electronic components 12, 15, and 16 may each include an active device or an active component. In some arrangements, the electronic components 12, 15, and 16 may each be or include circuits or circuit elements that rely on an external power supply to control or modify electrical signals. Examples of the active device may include an integrated circuit (IC), a chip, or a die that includes a semiconductor substrate, one or more integrated circuit devices and one or more overlying interconnection structures therein. For example, the electronic component 12 may include a controller, a processor, a central processing unit (CPU), a field-programmable gate array (FPGA), an application specific integrated circuit (ASIC), etc. The electronic component 12 may include a single chip or a plurality of chips.

The electronic components 12, 15, and 16 may each include a passive component or a passive device. In some arrangements, the electronic components 12, 15, and 16 may each be circuits or circuit elements that do not need an external power source to function and do not provide electrical gain. Examples of the passive device may include an inductance device (or an inductor), a capacitance device (or capacitor), a resistor, a diode, a fuse, an antifuse, etc. For example, the electronic components 15 and 16 may be passive devices of different types.

The positions, functions, and number of electronic components in the electronic device 1a are not intended to limit the present disclosure. For example, there may be any number of electronic components in the electronic device 1a due to design requirements. For example, the electronic component 15 (or a passive device) may be disposed over the carrier 11 or the carrier 13.

In some arrangements, the electronic component 12 may be disposed over and supported by the carrier 11. The electronic component 12 may be separated from the carrier 10 by the carrier 11. The electronic component 12 may be electrically connected to one or more other electrical components (if any) and to the carrier 11, and the electrical connections may be attained by way of flip-chip (such as by utilizing the electrical contact 12e) or wire-bond techniques. In some arrangements, the electronic component 12 may include a surface 121 facing the carrier 11 and a surface 122 opposite to the surface 121. The electrical contact 12e may be disposed adjacent to the surface 121. The surface 121 may be an active surface, a front surface, or a front side. The surface 122 may be a backside surface or a backside. Transistors and other active devices may be closer to the surface 121 then the surface 122.

In some arrangements, the electronic components 15 and 16 may each be disposed over the surface 102 of the carrier 10. For example, the electronic components 15 and 16 may each be directly connected to the surface 102 of the carrier 10. In some arrangements, in a direction (such as a horizontal direction) substantially parallel to the surface 101 and/or the surface 102 of the carrier 10, the electronic components 15 and 16 may each be overlapped with the carrier 11. In some arrangements, in a direction (such as a horizontal direction) substantially parallel to the surface 101 and/or the surface 102 of the carrier 10, the electronic components 15 and 16 may each be overlapped with the carrier 13.

In some arrangements, the optical component 14 may be disposed over and supported by the carrier 13. The optical component 14 may be separated from the carrier 10 by the carrier 13. The optical component 14 may be electrically connected to one or more other electrical components (if any) and to the carrier 13, and the electrical connections may be attained by way of flip-chip (such as by utilizing the electrical contact 14e) or wire-bond techniques.

In some arrangements, the electrical contacts 10e, 11e, 12e, 13e, and 14e may each include a reflowable conductive material, such as a soldering material. In some arrangements, the electrical contacts 10e, 11e, 12e, 13e, and 14e may each include one or more solder balls or solder bumps, such as a controlled collapse chip connection (C4) bump, a ball grid array (BGA) or a land grid array (LGA).

As mentioned, the optical component 14 may include a transceiver having the transmitter 14t and the receiver 14r. The transmitter 14t and the receiver 14r may be electrically connected with each other through the carrier 13.

The optical component 14 may be configured to support or provide the optical communication between the electronic device 1a and an external component. The optical component 14 may function as an optical transceiver and an optical interface that connects to an external component through a light carrying medium (which may include a fiber optic cable or an optical fiber). In some arrangements, the optical component 14 may include optical transmitters (such as the transmitter 14t), optical receivers (such as the receiver 14r), optical modulators, optical waveguides, optical splitters, optical combiners, optical grating couplers, etc.

In some arrangements, the transmitter 14t may include a light emitting diode (LED), a laser diode (such as vertical cavity surface-emitting laser (VCSEL)), a lamp, a laser, any other suitable light source, or a combination thereof. In some arrangements, the transmitter 14t may be arranged in an array (e.g., an LED array or a VCSEL array).

In some arrangements, the receiver 14r may include a photo-detector, a photo-sensor, a photodiode (PD), a charge-coupled device (CCD), a photomultiplier tube, a camera, a spectrometer, or another light-sensitive electronic device. In some arrangements, the receiver 14r may be arranged in an array (e.g., a PD array).

In some arrangements, the transmitter 14t may be referred to as a transmitting region and the receiver 14r may be referred to as a receiving region.

In some arrangements, the electronic component 12 may be configured to provide electronic functions for the optical component 14. More specifically, the electronic component 12 may be configured to control the optical component 14 and to process signals (including optical signals and electronic signals) sent to or received from the optical component 14.

In some arrangements, optical signals from an optical source external to the electronic device 1a may be received by, for example, the receiver 14r (e.g., a PD). The receiver 14r may convert optical signals into electrical signals that are communicated to electronic component 12 to process (e.g., analysis, modify, synthesize, convert to a digital signal, and amplify, etc.), to store, and/or to transmit the electrical signals. For example, the electrical signals from the receiver 14r may be sequentially transmitted through the carrier 13, the carrier 10, and the carrier 11. For example, the carrier 13, the carrier 10, and the carrier 11 may provide, define, construct, or establish an electrical path between the electronic component 12 and the optical component 14.

In some arrangements, the electronic component 12 (e.g., an ASIC) may generate electronic signals for driving the optical component 14. The electronic signals may be communicated to the transmitter 14t (e.g., an LED), which outputs optical signals. The transmitter 14t may convert electrical signals into optical signals. For example, the electrical signals may be sequentially transmitted through the carrier 11, the carrier 10, and the carrier 13.

The optical component 14 may include a partition 14p. The partition 14p may include a wall, a pillar, a shielding structure, a light blocking structure, etc. The partition 14p may be disposed over the carrier 13. The partition 14p may be affixed, connected, or attached to the carrier 13 through an adhesive layer 14g. The adhesive layer 14g may be disposed on a corner of the partition 14p. For example, the partition 14p may include a corner or a recess portion configured to accommodate the adhesive layer 14g. The adhesive layer 14g may include epoxy, resin, or other suitable materials, and may be a paste. The adhesive layer 14g may be thermally and/or optically cured. In some arrangements, the adhesive layer 14g may be non (low)-transmissive to the light emitted from the transmitter 14t. For example, the adhesive layer 14g may include an opaque material, such as ink, carbon black, photoresist, or other non (low)-transparent materials.

The partition 14p may encircle or surround the transmitter 14t and the receiver 14r. The partition 14p may separate or isolate the transmitter 14t from the receiver 14r.

The partition 14p may be configured to function as a light blocking structure. For example, the partition 14p may be non (low)-transmissive to the light emitted from the transmitter 14t. For example, the partition 14p may be configured to block, reflect, scatter, or absorb the light L1 emitted from the transmitter 14t. For example, the partition 14p may be configured to prevent undesired light from being inadvertently detected by the receiver 14r. For example, the partition 14p may be configured to reduce light crosstalk between the transmitter 14t and the receiver 14r.

In some arrangements, the carrier 13, the partition 14p, and/or the adhesive layer 14g may together form or constitute a light blocking structure.

The optical component 14 may include an optical element 14n. In some arrangements, the optical element 14n may form a convex lens (or a concave-convex lens) over one or more of the spaces or cubicles defined by the partition 14p. The optical element 14n may be affixed, connected, or attached to the partition 14p through the adhesive layer 14g.

The shape of the optical element 14n may be adjusted according to design requirements and is not intended to limit the present disclosure. For example, the optical element 14n may construct a panel, a waveguide, a prism, a concave lens, a convex lens, a flat surface, a diffuser, a shutter, a filter, a holographic element, a diffractive optical element (DOE), a meta lens, etc.

In some comparative arrangements, 2.3D or 2.5D technology can be employed to circumvent bandwidth limitations imposed by the carrier's pitch, enabling support for additional optical components. However, light-based sensing measurements may experience low signal-to-noise ratio (SNR) due to weak signals relative to background noise or light crosstalk.

According to some arrangements of the present disclosure, utilizing the carrier 13 to connect the optical component 14 to the carrier 10 allows for increased bandwidth without compromising package size. The carrier 13 can be a multi-functional interposer. This interposer not only enhances the efficiency of data transmission but also incorporates a light-blocking structure. Overall, the SNR can be increased, the problem of transmission loss can be solved, and detection can be improved. In addition, the carrier 13 can be bonded to the carrier 10 using low-temperature epoxy solder, minimizing thermal damage risk. Additionally, the carrier 13 and the carrier 10 feature different pitches, providing flexibility in component mounting to meet varying bandwidth requirements while maintaining a compact overall footprint.

FIG. 1B illustrates a cross-sectional view of an electronic device 1b in accordance with some arrangements of the present disclosure. The electronic device 1b in FIG. 1B is similar to the electronic device 1a in FIG. 1A except that the electronic device 1b further includes a supporting area 17 and a light carrying medium 18.

The supporting area 17 may include a fiber array supporting area. For example, the supporting area 17 may be configured to support the light carrying medium 18. The supporting area 17 may be disposed over the carrier 10 and may surround the carrier 13. From a cross-sectional view, the supporting area 17 may include two parts on opposite sides of the carrier 13.

The light carrying medium 18 may be affixed, connected, or attached to the supporting area 17 and the partition 14p through an adhesive layer 17g, which may have the same properties as the adhesive layer 14g.

The light carrying medium 18 may be supported over the optical component 14 by the supporting area 17 and the partition 14p.

The light carrying medium 18 may include an optical component. For example, the light carrying medium 18 may include an outer sheath 18s and multiple light paths (or light lanes) 18t. The light paths 18t may be aligned with the optical element 14n to couple optical signals from the transmitter 14t into the light carrying medium 18. The light paths 18t may be aligned with the optical element 14n to couple optical signals from the light carrying medium 18 into the receiver 14r.

In some arrangements, the light carrying medium 18 may include an array. The array of light carrying mediums 18 may, for example, be an M×N array of light paths 18t. For example, the light paths 18t may be arranged on a two dimensional (2D) surface. For example, the light paths 18t may be arranged along at least two dimensions or directions.

FIG. 1C illustrates a cross-sectional view of a part 1c of the electronic device of FIG. 1A in accordance with some arrangements of the present disclosure.

In FIG. 1C (a), the metal 13m be substantially coplanar with the surface 131 of the carrier 13. The surface 131 of the carrier 13 may be substantially parallel to the surface 101 and/or the surface 102 of the carrier 10. However, in some arrangements, the metal 13m be recessed with respect to the surface 131 of the carrier 13. For example, the metal 13m may have a recessed surface or a curved surface. The electrical contact 13e may be surrounded or covered by the resin 13r.

A part of the metal 13m may be exposed by the electrical contact 13e and contact (such as directly contact) the resin 13r. However, in some other arrangements, the electrical contact 13e may entirely cover the metal 13m.

In some arrangements, the electrical contact 13e may cover (such as entirely cover) the conductive pad 10p. However, in some other arrangements, a part of the conductive pad 10p may be exposed by the electrical contact 13e and contact (such as directly contact) the resin 13r.

In some arrangements, a dimension (such as a width) of the metal 13m may be greater than that of the conductive pad 10p. However, in some other arrangements, a dimension (such as a width) of the metal 13m may be substantially equal to that of the conductive pad 10p. For example, the sides of the metal 13m may be substantially aligned with that of the conductive pad 10p.

The electrical contact 13e may aggregate between the metal 13m and the conductive pad 10p during the curing process. For example, the electrical contact 13e may be overlapped with the metal 13m and the conductive pad 10p.

In some arrangements, a portion of the electrical contact 13e may bleed out from the conductive pad 10p. For example, in a direction (such as a horizontal direction) substantially parallel to the surface 102 of the carrier 10, the electrical contact 13e may be overlapped with the conductive pad 10p.

In FIG. 1C (b), the metal 13m protrudes from the surface 131 of the carrier 13. For example, the metal 13m may protrude or extend beyond the surface 131 of the carrier 13. For example, the metal 13m may protrude toward the carrier 10. The lateral surface 13m3 of the metal 13m may be exposed from the carrier 13. The resin 13r may cover, encapsulate, or contact the lateral surface 13m3 of the metal 13m.

In some arrangements, the space or distance D1 between the metal 13m and the conductive pad 10p in FIG. 1C (a) may be greater than the distance D2 between the metal 13m and the conductive pad 10p in FIG. 1C (b). The protruding structure of the metal 13m may decrease the amount or thickness of the electrical contact 13e and minimize crack issues that may occur in the electrical contact 13e.

The detailed properties and characteristics of the carrier 11 are similar to those of FIG. 1C and will not be repeated here for conciseness.

FIG. 1D, FIG. 1E, FIG. 1F, FIG. 1G, and FIG. 1H illustrates cross-sectional views of a part of an electronic device in accordance with some arrangements of the present disclosure.

In FIG. 1D, the optical element 14n may cover, surround, or encapsulate the transmitter 14t and the receiver 14r. The optical element 14n may include a convex profile over the tops of the transmitter 14t and the receiver 14r.

In FIG. 1E, the optical element 14n may be affixed, connected, or attached to the transmitter 14t and the receiver 14r through an adhesive layer 14a. The adhesive layer 14a may include a light transmissive material, such as clear glass, clear plastic, clear gel, clear resin, clear epoxy, sapphire, or other transparent materials. The adhesive layer 14a may be transparent to the light emitted from the transmitter 14t. The adhesive layer 14a may be transparent to the light detected by the receiver 14r.

In FIG. 1F, the optical element 14n may form a convex lens over one or more of the spaces or cubicles defined by the partition 14p. A light blocking layer 14b may be disposed under the optical element 14n. The light blocking layer 14b may be disposed on planar portions of the optical element 14n, and the optical element 14n may include a convex profile among the light blocking layer 14b. For example, in a cross-sectional view, the convex surfaces may protrude from the light blocking layer 14b. The light blocking layer 14b may include an opaque material, such as ink, carbon black, photoresist, or other non (low)-transparent materials. The light blocking layer 14b may contact the adhesive layer 14g. The adhesive layer 14g may be disposed between the light blocking layer 14b and the partition 14p.

In FIG. 1G, the partition 14p in FIG. 1F may be omitted, and the optical element 14n may include an extending portion extending from the convex lens to the transmitter 14t and the receiver 14r. The extending portion may support the convex lens. In some arrangements, the optical element 14n may contact (such as directly contact) the transmitter 14t and the receiver 14r. In some arrangements, the optical element 14n may be affixed, connected, or attached to the transmitter 14t and the receiver 14r through an adhesive layer (such as the adhesive layer 14g) in FIG. 1A. For example, adhesive layer may be disposed on a corner of the optical element 14n. For example, the optical element 14n may include a corner or a recess portion configured to accommodate the adhesive layer.

The arrangement, profile, or contour of the optical element 14n may be adjusted based on designed requirements and is not limited thereto. The optical component 14 in FIG. 1A may be replaced with the structures in FIG. 1D, FIG. 1E, FIG. 1F, and FIG. 1G.

In FIG. 1H, the transmitter 14t may include an LED array integrated as a component. The receiver 14r may include a PD array integrated as a component. The transmitter 14t and the receiver 14r in FIG. 1A may be replaced with the structures in FIG. 1H.

FIG. 1I illustrates a cross-sectional view of an electronic device 1i in accordance with some arrangements of the present disclosure. The electronic device 1i in FIG. 1I is similar to the electronic device 1a in FIG. 1A except that the carrier 11 in FIG. 1A is replaced with the carrier 19. The carrier 19 may include a silicon interposer.

In some arrangements, the carrier 19 may connect multiple chips (such as electronic component 12) in a 2.5D packaging architecture. The carrier 19 may include a substrate having a silicon material, and a plurality of vias 19v. The vias 19v may include through silicon vias (TSV) for vertical interconnections.

The choice between a silicon interposer (such as the carrier 19) and a fine pitch interposer (such as the carrier 11) depends on the specific requirements of the application, including performance, density, and cost considerations. Similarly, the carrier 13 in FIG. 1A may be replaced with the carrier 19.

FIG. 1J illustrates a perspective view of an electronic device 1j in accordance with some arrangements of the present disclosure. The electronic device 1j in FIG. 1J is similar to the electronic device 1a in FIG. 1A except for the following differences.

The electronic device 1j may include a plurality of electronic components 15 disposed around the optical component 14. The optical component 14 in the electronic device 1j may include the transmitter 14t (or a transmitting region) and the receiver 14r (or a receiving region) integrated on a carrier 14c. The electronic device 1j may include a supporting area 17. The supporting area 17 may include a fiber array supporting area. For example, the supporting area 17 may be configured to support the light carrying medium 18 in FIG. 1B.

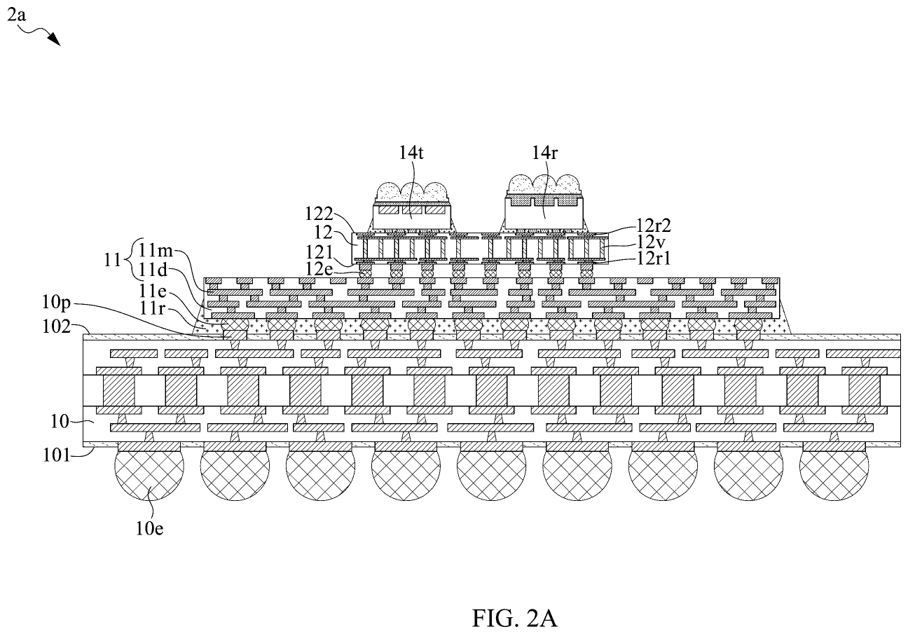

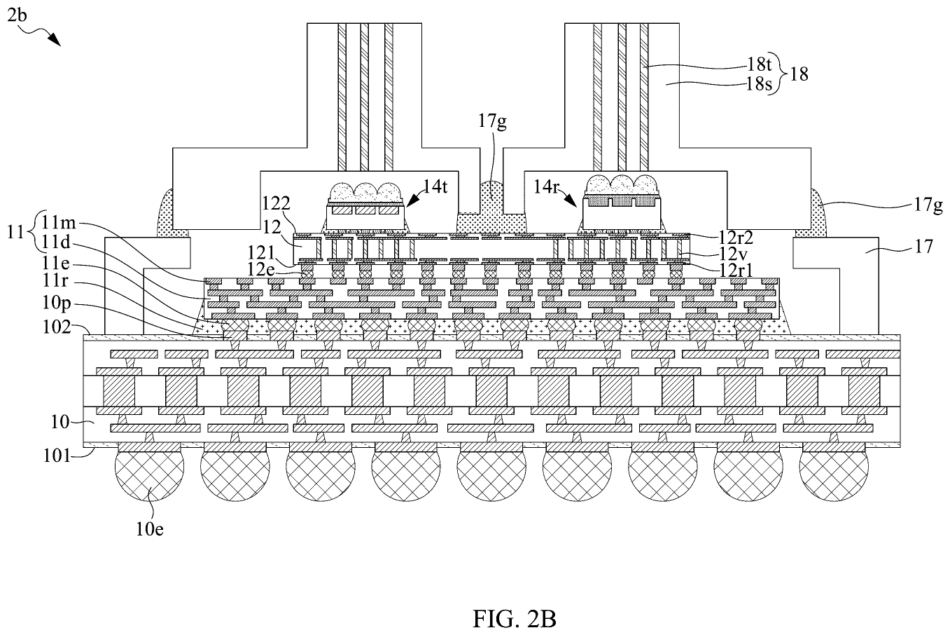

FIG. 2A illustrates a cross-sectional view of an electronic device 2a in accordance with some arrangements of the present disclosure. The electronic device 2a in FIG. 2A is similar to the electronic device 1a in FIG. 1A except for the following differences.

The optical component 14 and the electronic component 12 in FIG. 1A may be next to each other or side-by-side. For example, the optical component 14 and the electronic component 12 in FIG. 1A may be at least partially overlapped in a direction (such as a horizontal direction) substantially parallel to the surface 101 and/or the surface 102 of the carrier 10.

The optical component 14 may be stacked over the electronic component 12 in FIG. 2A. For example, the optical component 14 and the electronic component 12 in FIG. 2A may be at least partially overlapped in a direction (such as a vertical direction) substantially perpendicular to the surface 101 and/or the surface 102 of the carrier 10.

The optical component 14 may be supported by the electronic component 12, and the carrier 13 in FIG. 1A may be omitted. The electronic component 12 may support the optical component 14. The electronic component 12 may be supported by the carrier 11. The electronic component 12 may include one or more conductive vias 12v. For example, the electronic component 12 may include a body (or a main body) and the conductive vias 12v may at least partially penetrate the body. In some arrangements, the conductive vias 12v may connect between redistribution layers 12r1 and 12r2. The redistribution layer 12r2 may be adjacent to the backside surface (such as the surface 122) of the electronic component 12. The redistribution layer 12r1 may be adjacent to the active surface (such as the surface 121) of the electronic component 12. The redistribution layer 12r2 may be at least partially exposed by the surface 122 of the electronic component 12. The carrier 10, the carrier 11, the electronic component 12 may be configured to provide, define, construct, or establish one or more electrical paths for the optical component 14. The electronic component 12 may be electrically connected with the carrier 11 through the conductive vias 12v, and the redistribution layers 12r1 and 12r2. The electronic component 12 may be electrically connected with the optical component 14 through the conductive vias 12v, and the redistribution layers 12r1 and 12r2.

In some other arrangements, the surface 121 (which may be an active surface, a front surface, or a front side) may face the optical component 14. The surface 122 (which may be a backside surface or a backside) may face the carrier 11.

The optical component 14 in FIG. 2A may be replaced with the structures in FIG. 1A, FIG. 1D, FIG. 1F, and FIG. 1G.

FIG. 2B illustrates a cross-sectional view of an electronic device 2b in accordance with some arrangements of the present disclosure. The electronic device 2b in FIG. 2B is similar to the electronic device 2a in FIG. 2A except that the electronic device 2b further includes the supporting area 17 and the light carrying medium 18.

The supporting area 17 may be disposed over the carrier 10 and may surround the carrier 11. From a cross-sectional view, the supporting area 17 may include two parts on opposite sides of the carrier 11. The light carrying medium 18 may be affixed, connected, or attached to the supporting area 17 and the carrier 12 through the adhesive layer 17g. For example, the adhesive layer 17g may be disposed over the electronic component 12 to connect the light carrying medium 18. For example, the adhesive layer 17g may directly contact the backside surface (such as the surface 122) of the electronic component 12. The adhesive layer 17g on the carrier 12 may be disposed between the transmitter 14t and the receiver 14r.

In some arrangements, the adhesive layer 17g may be configured to function as a light blocking structure. The adhesive layer 17g may be non-transmissive to the light emitted from the transmitter 14t. For example, the adhesive layer 17g may be configured to block, reflect, scatter, or absorb the light emitted from the transmitter 14t. For example, the adhesive layer 17g may be configured to prevent undesired light from being inadvertently detected by the receiver 14r. For example, the adhesive layer 17g may be configured to reduce light crosstalk (optical signal crosstalk or optical crosstalk) between the transmitter 14t and the receiver 14r.

The detailed properties and characteristics of the supporting area 17 and the light carrying medium 18 are similar to those of FIG. 1B and will not be repeated here for conciseness.

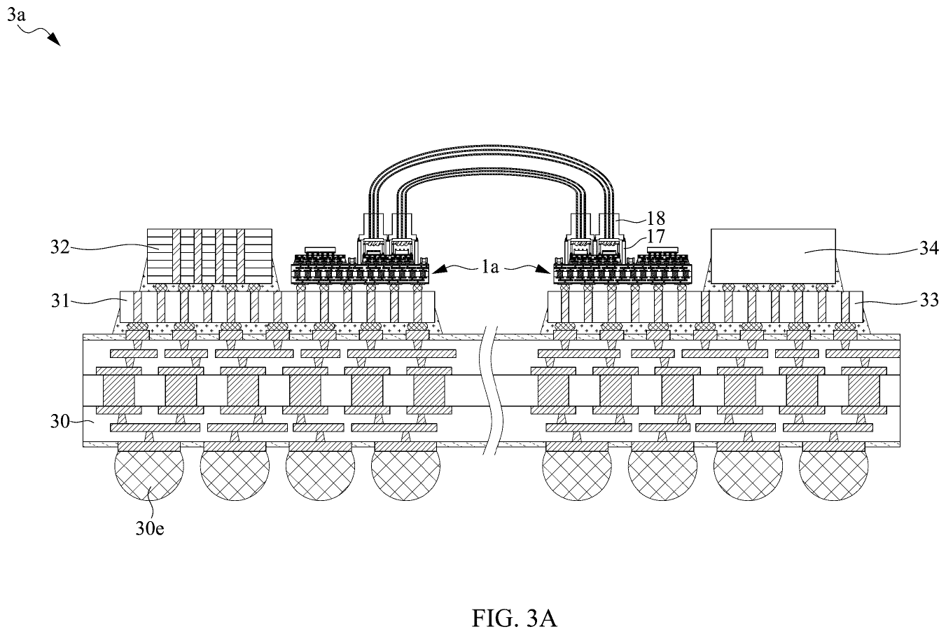

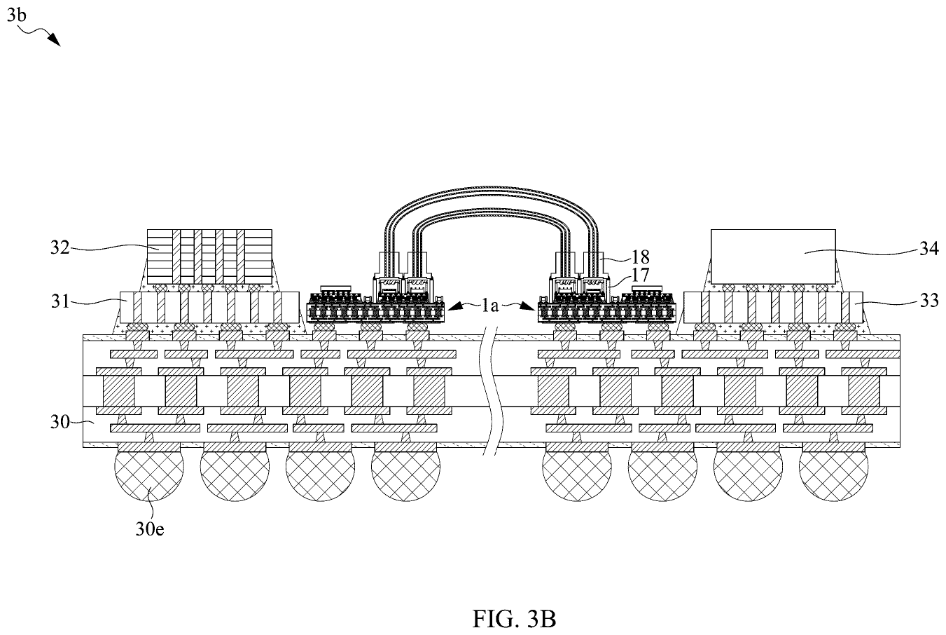

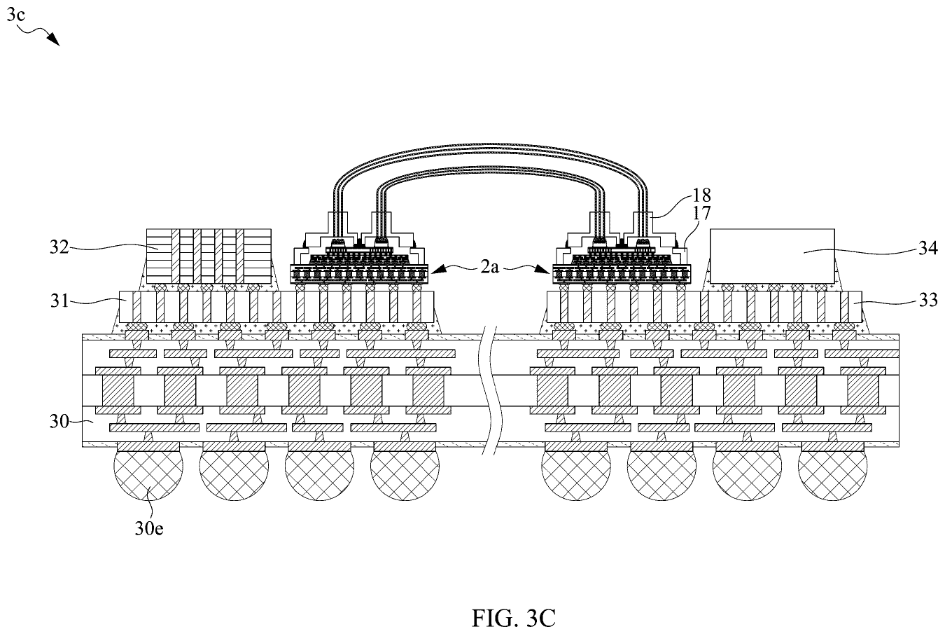

FIG. 3A illustrates a cross-sectional view of an electronic device 3a in accordance with some arrangements of the present disclosure.

In some arrangements, the electronic device 3a may include a system-in-package (SiP) module. The electronic device 3a may include the electronic device 1a, carriers 30, 31, 33, electronic components 32, 34, the supporting area 17, and the light carrying medium 18.

The electronic devices 1a may be disposed over the carrier 31 and the carrier 33. The supporting area 17 and the light carrying medium 18 may be disposed over the electronic device 1a. The detailed properties and characteristics of the electronic device 1a are similar to those of FIG. 1A and will not be repeated here for conciseness. The electronic device 1a may be replaced by the electronic device 1i, the electronic device 1j, or the electronic device 2a.

The detailed properties and characteristics of the carrier 30 are similar to those of the carrier 10 and will not be repeated here for conciseness. In some arrangements, the carrier 30 may include an electrical contact 30e for providing electrical connections between the electronic device 3a and an external device (e.g., a PCB, an electronic device, an electronic module, and so on).

The detailed properties and characteristics of the carriers 31 and 33 are similar to those of the carrier 19 and will not be repeated here for conciseness.

In some arrangements, the electronic component 32 may include a non-volatile memory (such as a flash memory and a read-only memory (ROM)) or a volatile memory (such as a Dynamic Random Access Memory (DRAM)). In some arrangements, the active component 32 may include a high bandwidth memory (HBM).

The detailed properties and characteristics of the electronic component 34 are similar to those of the electronic component 12 and will not be repeated here for conciseness.

The light carrying medium 18 may connect between two electronic devices 1a to facilitate the propagation of light waves. For example, an optical signal emitted from the transmitter of one of the electronic devices 1a may be transmitted to a receiver of another one of the electronic devices 1a through the light carrying medium 18.

FIG. 3B illustrates a cross-sectional view of an electronic device 3b in accordance with some arrangements of the present disclosure. The electronic device 3b in FIG. 3B is similar to the electronic device 3a in FIG. 3A except that the carrier 31 supports the electronic component 32, and the electronic device 1a on the left side is directly connected to the carrier 30.

Similarly, the carrier 33 may support the electronic component 34, and the electronic device 1a on the right side is directly connected to the carrier 30. The arrangements of the electronic device 1a may be chosen depending on the specific requirements of the application, including performance, density, and cost considerations.

FIG. 3C illustrates a cross-sectional view of an electronic device 3c in accordance with some arrangements of the present disclosure. The electronic device 3c in FIG. 3C is similar to the electronic device 3a in FIG. 3A except that the electronic device 1a is replaced by the electronic device 2a.

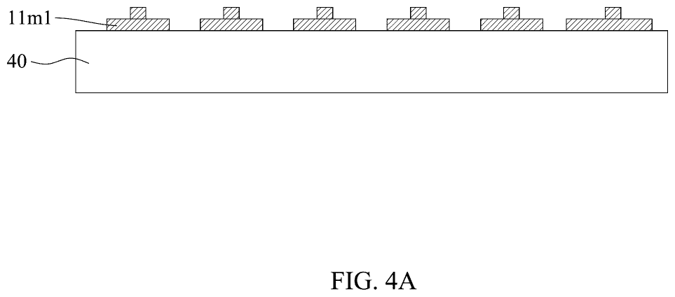

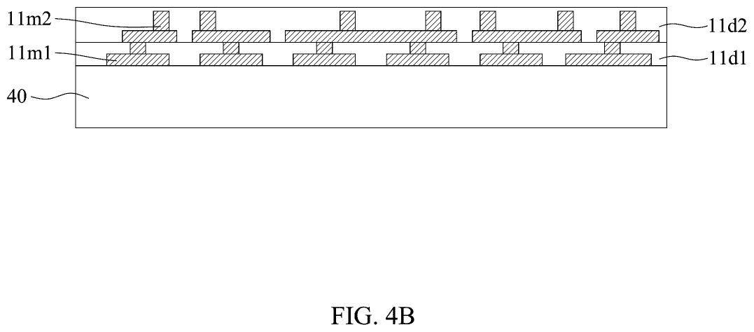

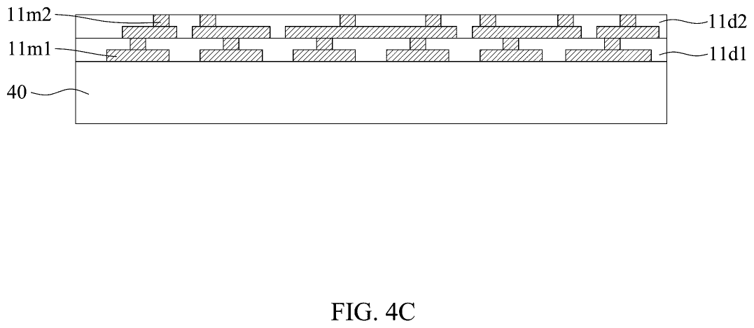

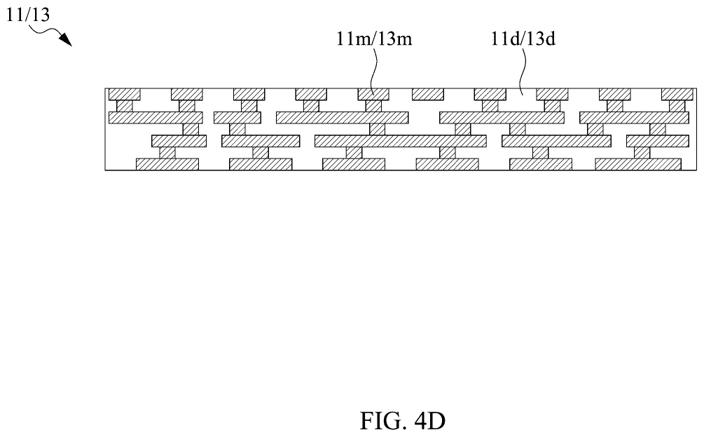

FIG. 4A, FIG. 4B, FIG. 4C, and FIG. 4D illustrate cross-sectional views in one or more stages of a method of manufacturing a part of an electronic device in accordance with an embodiment of the present disclosure. At least some of these figures have been simplified to better understand the aspects of the present disclosure. In some arrangements, the carriers 11 and 13 may be manufactured through the steps illustrated in FIG. 4A, FIG. 4B, FIG. 4C, and FIG. 4D.

Referring to FIG. 4A, a temporary carrier 40 may be provided (e.g., manufactured). The temporary carrier 40 may include temporary or base material such as silicon, polymer, polymer composite, metal, ceramic, glass, glass epoxy, beryllium oxide, or other suitable low-cost, rigid material or bulk semiconductor material for structural support. A first metal layer 11m1 may be formed over the temporary carrier 40 through, for example, an electroplating operation. In some arrangements, the first metal layer 11m1 may include a conductive material such as metal or a metal alloy. Examples of the conductive material include gold (Au), silver (Ag), aluminum (Al), copper (Cu), platinum (Pt), Palladium (Pd), other metal(s) or alloy(s), or a combination thereof.

Referring to FIG. 4B, a first dielectric layer 11d1 may be disposed over the temporary carrier 40 and cover the first metal layer 11m1. In some arrangements, the first dielectric layer 11d1 may be formed by a compression molding operation. A portion of the first dielectric layer 11d1 may be removed to expose a portion of the first metal layer 11m1. In some arrangements, the first dielectric layer 11d1 may be removed through, for example, a grinding operation.

A second metal layer 11m 2 may be formed over the first dielectric layer 11d1 through, for example, an electroplating operation. Then, a second dielectric layer 11d2 may be disposed over the first dielectric layer 11d1 and cover the second metal layer 11m 2.

Referring to FIG. 4C, a portion of the second dielectric layer 11d2 may be removed to expose a portion of the second metal layer 11m2. In some arrangements, the second dielectric layer 11d2 may be removed through, for example, a grinding operation.

The operations of electroplating, compression molding, and grinding may be repeated according to the number of layers in the carriers 11 and 13.

Referring to FIG. 4D, the temporary carrier 40 may be removed from the first dielectric layer 11d1 to expose the first metal layer 11m1.

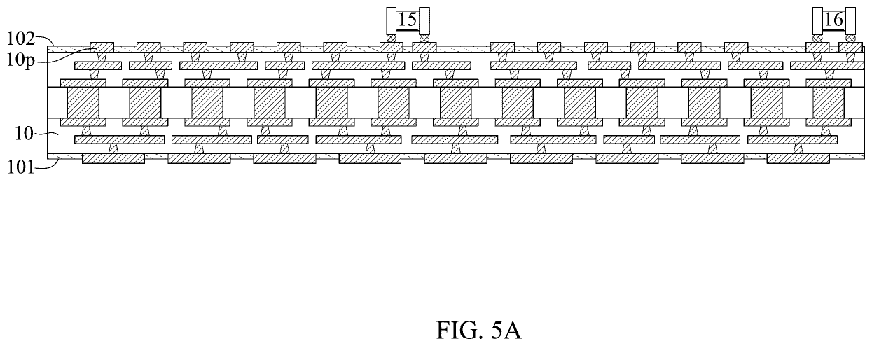

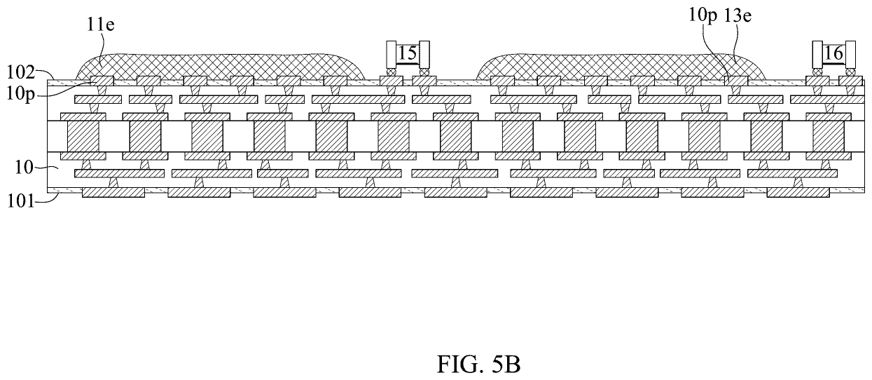

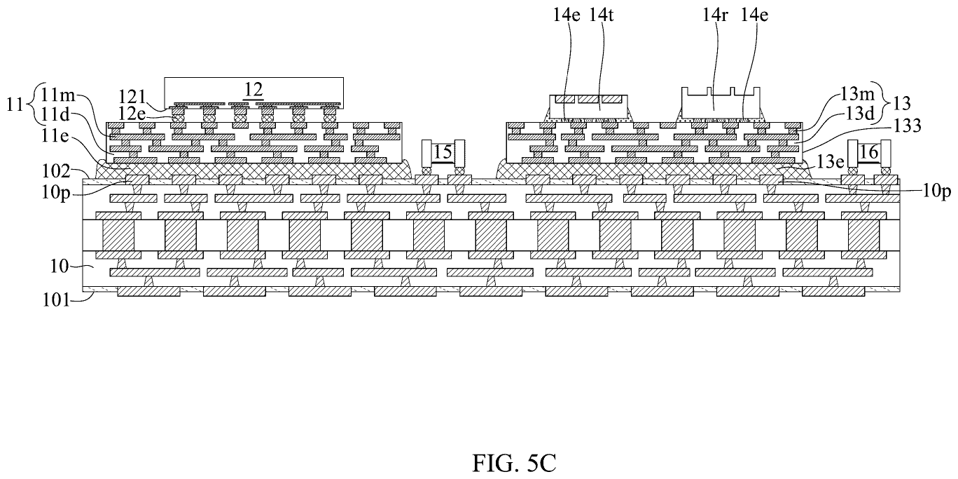

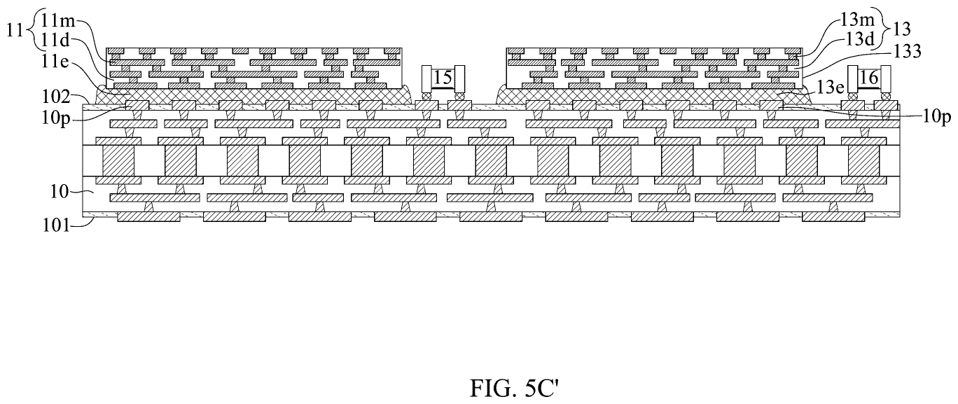

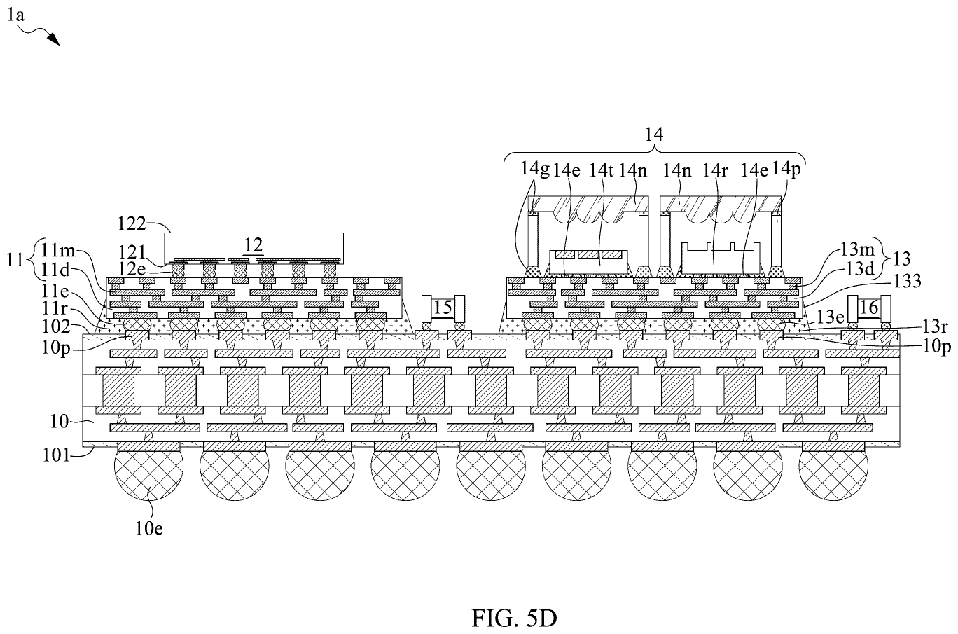

FIG. 5A, FIG. 5B, FIG. 5C, and FIG. 5D illustrate cross-sectional views in one or more stages of a method of manufacturing an electronic device in accordance with an embodiment of the present disclosure. At least some of these figures have been simplified to better understand the aspects of the present disclosure. In some arrangements, the electronic device 1a may be manufactured through the steps illustrated in FIG. 5A, FIG. 5B, FIG. 5C, and FIG. 5D.

Referring to FIG. 5A, the carrier 10 may be provided. The carrier 10 may include conductive pads 10p adjacent to the surface 102 of the carrier 10. The electronic components 15 and 16 may be disposed over the carrier 10.

Referring to FIG. 5B, the epoxy solder paste of the electrical contacts 11e and 13e may be dispensed over the carrier 10.

Referring to FIG. 5C, the carrier 11, along with the electronic component 12, may be disposed over the carrier 10. The carrier 13, along with the optical component 14, may be disposed over the carrier 10.

Referring to FIG. 5D, a curing operation may be conducted to melt the epoxy solder paste, forming the electrical contacts 11e and 13e. The electrical contact 10e may be disposed on the carrier 10. The partition 14p and the optical element 14n may be disposed over the carrier 13.

A singulation may be performed to separate out individual electronic device 1a. The singulation may be performed, for example, by using a dicing saw, laser or other appropriate cutting techniques. In some arrangements, an optical test may be conducted.

In some arrangements, the carrier 11 and the carrier 13 may be disposed over the carrier 10 before disposing the electronic component 12 and the optical component 14. For example, referring to FIG. 5C', the carrier 11 and the carrier 13 may be disposed over the carrier 10. Then, the electronic component 12 may be disposed over the carrier 11 and the optical component 14 may be disposed over the carrier 13.

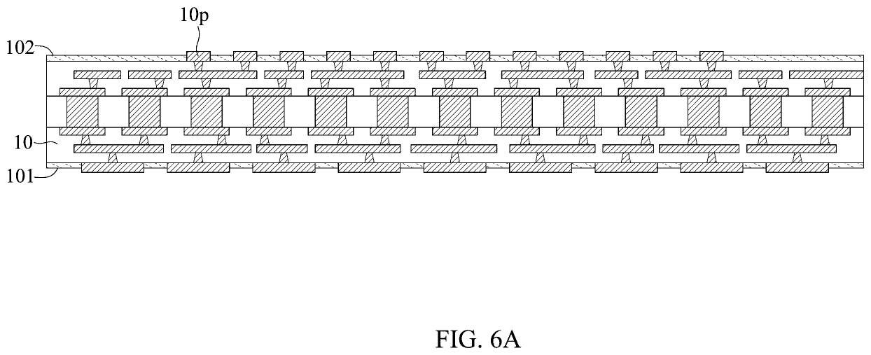

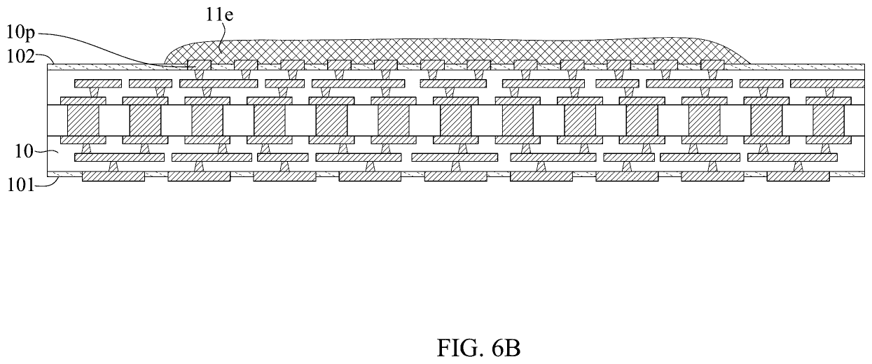

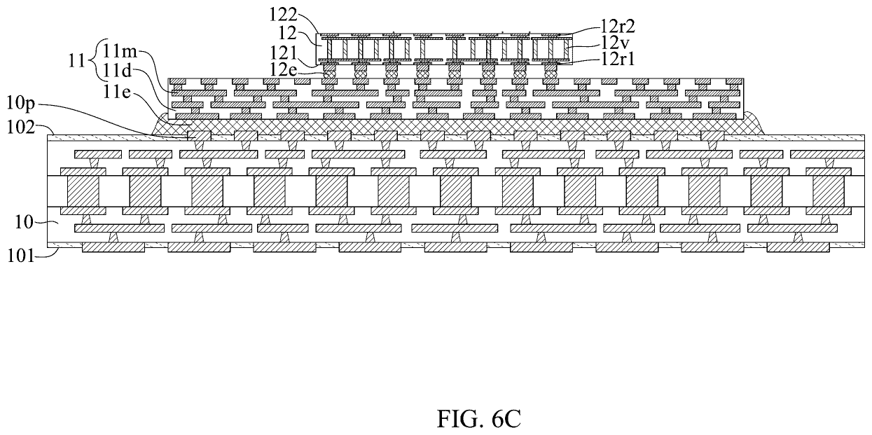

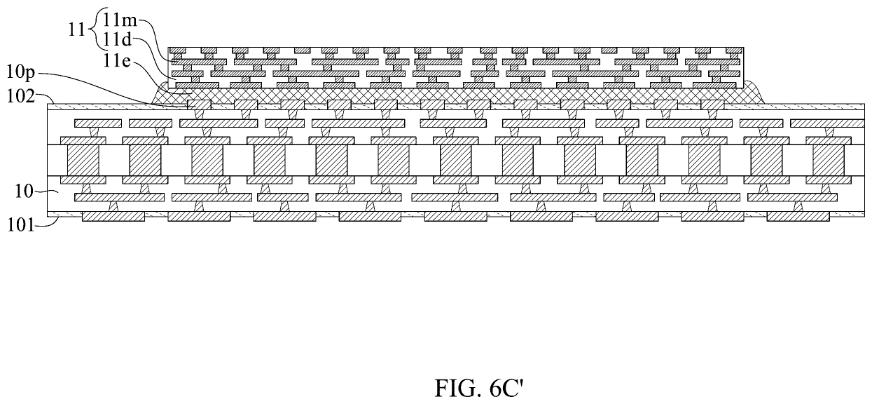

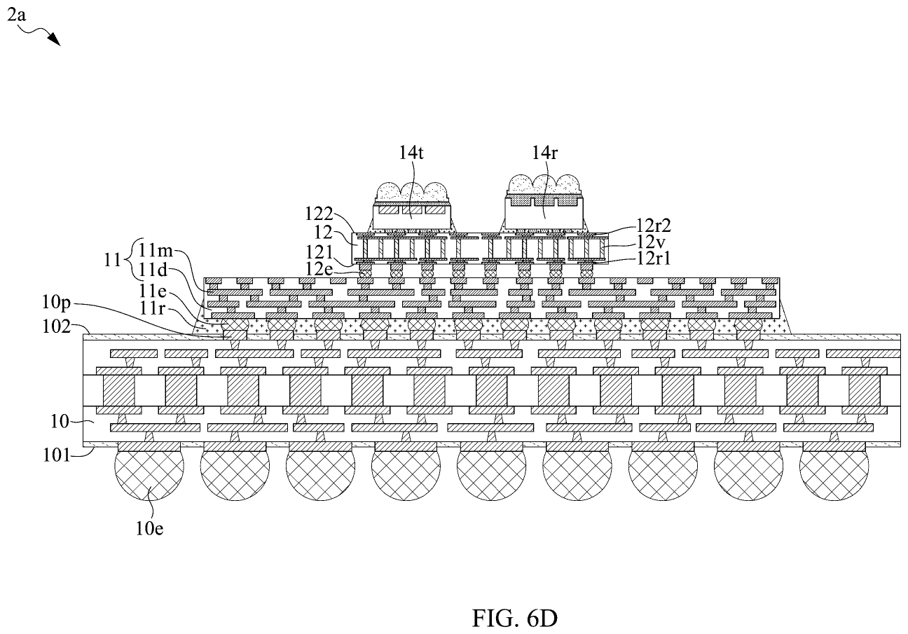

FIG. 6A, FIG. 6B, FIG. 6C, and FIG. 6D illustrate cross-sectional views in one or more stages of a method of manufacturing an electronic device in accordance with an embodiment of the present disclosure. At least some of these figures have been simplified to better understand the aspects of the present disclosure. In some arrangements, the electronic device 2a may be manufactured through the steps illustrated in FIG. 6A, FIG. 6B, FIG. 6C, and FIG. 6D.

Referring to FIG. 6A, the carrier 10 may be provided. The carrier 10 may include conductive pads 10p adjacent to the surface 102 of the carrier 10.

Referring to FIG. 6B, the epoxy solder paste of the electrical contacts 11e may be dispensed over the carrier 10.

Referring to FIG. 6C, the carrier 11, along with the electronic component 12, may be disposed over the carrier 10.

Referring to FIG. 6D, a curing operation may be conducted to melt the epoxy solder paste, forming the electrical contacts 11e. The electrical contact 10e may be disposed on the carrier 10. The optical component 14 may be disposed over the electronic component 12.

A singulation may be performed to separate out individual electronic device 1a. The singulation may be performed, for example, by using a dicing saw, laser or other appropriate cutting techniques. In some arrangements, an optical test may be conducted.

In some arrangements, the carrier 11 may be disposed over the carrier 10 before disposing the electronic component 12. For example, referring to FIG. 6C', the carrier 11 may be disposed over the carrier 10. Then, the electronic component 12 may be disposed over the carrier 11.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a carrier;
an interposer disposed over the carrier;
an optical transceiver disposed over the interposer; and
an electronic component supporting optical transceiver and supported by the interposer.

2. The electronic device of claim 1, wherein a conductive terminal of the interposer protrudes from a surface of the interposer toward the carrier.

3. The electronic device of claim 2, further comprising:
a connection layer having a conductive element and an encapsulant, wherein the conductive element connecting the carrier to the conductive terminal of the interposer, and wherein the encapsulant encapsulating the conductive element and a lateral surface of the conductive terminal of the interposer.

4. The electronic device of claim 3, wherein the encapsulant encapsulates a lateral surface of the interposer.

5. The electronic device of claim 1, wherein the electronic component has a front side facing the optical transceiver and a backside opposite to the front side, the backside faces the interposer.

6. The electronic device of claim 5, wherein the electronic component has a first redistribution layer adjacent to the front side.

7. The electronic device of claim 6, wherein the electronic component has a body and a conductive via at least partially penetrating the body, wherein the electronic component is electrically connected with the interposer through the conductive via.

8. The electronic device of claim 7, wherein the electronic component has a second redistribution layer adjacent to the backside, and the conductive via is electrically connected with the interposer through the second redistribution layer.

9. The electronic device of claim 1, further comprising:
an optical component connecting to the optical transceiver and configured to transmit an optical signal.

10. The electronic device of claim 9, wherein the carrier supports the optical component.

11. The electronic device of claim 9, further comprising:
a connection element connecting the optical component to the electronic component, wherein the connection element is configured to block an optical crosstalk between a transmitter and a receiver of the optical transceiver.

12. An electronic device, comprising:
a lower-density circuit;
a first higher-density circuit disposed over the lower-density circuit; and
an optical transceiver disposed over the first higher-density circuit and including a transmitting region and a receiving region;
wherein the first higher-density circuit is configured to reduce optical crosstalk between the transmitting region and the receiving region.

13. The electronic device of claim 12, wherein the first higher-density circuit is connected with the lower-density circuit through a conductive paste.

14. The electronic device of claim 12, further comprising:
a passive component disposed over the first higher-density circuit or the lower-density circuit.

15. The electronic device of claim 12, further comprising:
a second higher-density circuit disposed over the lower-density circuit; and
an integrated circuit disposed over the second higher-density circuit, wherein an electrical path between the integrated circuit and the optical transceiver is established through the second higher-density circuit, the lower-density circuit, and the first higher-density circuit.

16. The electronic device of claim 12, further comprising:
a partition disposed over the first higher-density circuit, and between the transmitting region and the receiving region, wherein the partition is configured to support an optical component.

17. An electronic device, comprising:
a circuit structure;
an optical transceiver disposed over the circuit structure and including a transmitting region and a receiving region; and
a first light blocking structure supporting the optical transceiver and configured to reduce an optical crosstalk between the transmitting region and the receiving region.

18. The electronic device of claim 17, further comprising:
a second light blocking structure disposed over the first light blocking structure, and between the transmitting region and the receiving region.

19. The electronic device of claim 17, wherein the first light blocking structure includes a conductive layer and a light blocking layer covering the conductive layer.

20. The electronic device of claim 19, wherein the light blocking layer includes a molding compound or ajinomoto build-up film (ABF).
